(19) United States
(12) Patent Application Publication
(10) Pub. No.: US 2022/0403565 A1
(43) Pub. Date: Dec. 22, 2022

(54) FLEXIBLE MAGNETIC FILM FABRIC

(71) Applicant: 3M INNOVATIVE PROPERTIES COMPANY, St. Paul, MN (US)

(72) Inventors: Wataru Nakayama, Tokyo (JP); Kazuhiko Mizuno, Tokyo (JP); Kentaro Tamura, Tokyo (JP); Akihiko Mitsui, Tokyo (JP)

(21) Appl. No.: 17/642,877

(22) PCT Filed: Aug. 28, 2020
(86) PCT No.: PCT/IB2020/058048

§ 371 Date: Mar. 14, 2022

(30) Foreign Application Priority Data
Sep. 19, 2019 (JP) 2019-170600

(51) Int. Cl. D03D 1/00; D03D 13/00; D03D 15/46; D03D 15/507; H01F 1/153; H01F 1/28; H01F 1/37; H05K 9/00

(52) U.S. Cl. CPC D03D 1/0058; D03D 13/002; D03D 15/46; D03D 15/507; H01F 1/15375; H01F 1/28; H01F 1/37; H05K 9/0075; H05K 9/009

(57) ABSTRACT

To provide an electromagnetic shielding material that has excellent shape following properties and can exhibit high electromagnetic wave shielding properties even in a deformed portion. A flexible magnetic film fabric (100) of one embodiment includes a plurality of first magnetic strips (10) extending in a first direction (11) and arranged substantially in parallel at a first pitch P1 along a second direction (12) orthogonal to the first direction (11); and a plurality of second magnetic strips (20) extending in a third direction (21) different from the first direction (11) and arranged substantially in parallel at a second pitch P2 along a fourth direction (22) orthogonal to the third direction (21). Each of the first magnetic strips (10) has a first average width W1, W1/P1 being from 0.05 to 0.98, and each of the second magnetic strips (20) has a second average width W2, W2/P2 being from 0.05 to 0.98.

### TECHNICAL FIELD

The present disclosure relates to a flexible magnetic film fabric.

### BACKGROUND

Electromagnetic shielding materials are known as materials for shielding electrical and electronic parts, or electrical and electronic devices. Such electrical and electronic parts/devices include: personal computers, cell phones, household appliances and parts thereof, motors for vehicles that use electricity as their partial or entire energy source, inverters, and wire harnesses.

Patent Document 1 (JP 2004-277964 A) describes “an electromagnetic shielding woven fabric that uses a soft magnetic wire material in which soft magnetic metal powder is dispersed in a rubber or a matrix of synthetic resin, in at least one of warp or weft threads.”

Patent Document 2 (JP 10-259641 A) describes “an electromagnetic shielding material obtained by weaving a first warp yarn made of multifilament carbon fiber, a second warp yarn of ferromagnetic material interspersed with the first warp yarn, and a ferromagnetic weft that intersects the first and second warp yarns.”

Patent Document 3 (JP 2014-045047 A) describes “an electromagnetic wave shielding electromagnetic wave shielding material that is formed by a metal plating applied to a surface of a metal woven fabric formed by intersecting non-metallic fibers and metal lines.”

Patent Document 4 (JP 2001-226873 A) describes “an electrically conductive fiber material comprising a fabric composed of a thermoplastic fiber multifilament yarn composed of a large number of flat single threads and a metal covering layer.”

Patent Document 5 (JP 2000-049489 A) discloses “an electromagnetic shield body in which an electromagnetic wave shielding sheet is integrated with a molded body, the molded body molded into a certain form by die forming processing, the electromagnetic wave shielding sheet integrated with at least a portion of a front surface or a back surface of the molded body along the shape of the molded body, the electromagnetic wave shielding sheet comprising fabric and a conductive film, wherein the fabric is a woven or knitted fabric that is flexible and develops stretchability as the weave pattern or stitches deform, and wherein the conductive film covers the surface of the yarn forming the weave pattern or stiches, and is deformable when following deformation of the yarn that forms the weave pattern or stitches of the fabric.”

Patent Document 6 (JP 2000-151182 A) discloses “an electromagnetic wave shield fabric in which the fabric pattern is formed through a positional relationship of one of the intersecting warp and weft being “raised” or “sunken” with respect to the other, and in a fabric in which the warp and weft described above contain an electromagnetic shielding yarn, when the “interlacing strength” of an intersection point X is defined as “out of four intersection points on a warp and a weft constituting and adjacent to an arbitrary intersection point X, the number of intersection points with intersecting status (raised or sunken) opposite to that of the intersection point X”, the electromagnetic shielding yarns are disposed so as to interlace at a point on which the interlacing strength is four.”

Patent Document 7 (JP 2018-116954 A) discloses “an electromagnetic shield having a braided structure in which warp threads and skewed threads are braided, each of the warp thread and the skewed thread being constituted by a plurality of filaments, wherein the warp threads comprise conductive filaments, and the skewed threads comprise conductive filaments and nonconductive filaments.”

### CITATION LIST

### Patent Documents

Patent Document 1: JP 2004-277964 A

Patent Document 2: JP 10-259641 A

Patent Document 3: JP 2014-045047 A

Patent Document 4: JP 2001-226873 A

Patent Document 5: JP 2000-049489 A

Patent Document 6: JP 2000-151182 A

Patent Document 7: JP 2018-116954 A

### SUMMARY

### Technical Problem

For example, for the purpose of reducing the weight of a vehicle such as an electric vehicle, changing the material of the housing or container from metal to resin is being contemplated, for which electromagnetic wave shielding properties are required. Electromagnetic shielding materials are desired that are readily applicable to articles having three-dimensional shapes, such as resin housings or resin containers, and exhibit electromagnetic wave shielding properties even in deformed portions.

The present disclosure provides an electromagnetic shielding material that has excellent shape following properties and can exhibit high electromagnetic wave shielding properties even in a deformed portion.

### Solution to Problem

The present inventors discovered that by weaving a strip of magnetic material in a predetermined size and arrangement, it is possible to impart flexibility to the electromagnetic shielding material, and to achieve high electromagnetic shielding properties even in the deformed portion.

According to one embodiment of the present disclosure, there is provided a flexible magnetic film fabric (100) including: a plurality of first magnetic strips (10) extending in a first direction (11) and arranged substantially in parallel at a first pitch P1 along a second direction (12) orthogonal to the first direction (11); and a plurality of second magnetic strips (20) extending in a third direction (21) different from the first direction (11) and arranged substantially in parallel at a second pitch P2 along a fourth direction (22) orthogonal to the third direction (21); in which each of the first magnetic strips (10) has a first average width W1, W1/P1 being from 0.05 to 0.98, in which each of the second magnetic strips (20) has a second average width W2, W2/P2 being from 0.05 to 0.98.

According to another embodiment of the present disclosure, there is provided a flexible magnetic film fabric (100) including a plurality of magnetic strips (10, 20) extending in at least two different directions (11, 21), each of the plurality of magnetic strips (10, 20) comprising at least two spaced-apart magnetic layers (40) stacked in a thickness direction of the magnetic strip (10, 20), in which the flexible magnetic film fabric (100) is configured, when it is made to follow vertices or edges of a cube, to be reversibly deformable to the shape of the cube, without damage or with no substantial damage to the magnetic strip (10, 20).

### Advantageous Effects of Invention

According to the present disclosure, it is possible to provide an electromagnetic shielding material that has excellent shape following properties and can exhibit high electromagnetic wave shielding properties even in a deformed portion.

Note that the above description should not be construed to mean that all embodiments of the present invention and all advantages related to the present invention are disclosed.

### BRIEF DESCRIPTION OF THE DRAWINGS

FIG. 1 is a plan view of a flexible magnetic film fabric of one embodiment.

FIG. 2 is a plan view of a flexible magnetic film fabric of another embodiment.

FIG. 3 is a perspective view of a magnetic strip of an embodiment.

FIG. 4 is a schematic cross-sectional view of a magnetic strip according to another embodiment.

FIG. 5 is a graph of W1/P1 (W2/P2) vs. shielding effect.

FIG. 6A is a graph showing the frequency dependence of the shielding effect of a sample of Example 3 (W1/P1=0.50, W2/P2=0.50).

FIG. 6B is a graph showing the frequency dependence of the shielding effect of a sample of Example 14 (W1/P1=0.91, W2/P2=0.20).

FIG. 7 is a graph showing the frequency dependence of the shielding effect of the samples of Example 3 and Comparative Example 2.

### DESCRIPTION OF EMBODIMENTS

Hereinafter, the present invention will be described in more detail to exemplify representative embodiments of the present invention, but the present invention is not limited to these embodiments. As for the reference signs in the drawings, elements denoted by the similar reference signs in different drawings indicate similar or corresponding elements.

The flexible magnetic film fabric 100 of the first embodiment includes a plurality of first magnetic strips 10 extending in a first direction 11 and arranged substantially in parallel at a first pitch P1 along a second direction 12 orthogonal to the first direction 11; and a plurality of second magnetic strips 20 extending in a third direction 21 different from the first direction 11 and arranged substantially in parallel at a second pitch P2 along a fourth direction 22 orthogonal to the third direction 21. Each of the first magnetic strips 10 has a first average width W1, W1/P1 being from 0.05 to 0.98, and each of the second magnetic strips 20 has a second average width W2, W2/P2 being from 0.05 to 0.98.

The flexible magnetic film fabric of the present disclosure has a woven structure in which when an external force is applied, the magnetic strips can be displaced from each other to release the force. Therefore, the flexible magnetic film fabric of the present disclosure has excellent shape following properties, and it is capable of suppressing a deterioration in electromagnetic wave shielding properties caused by damage to the magnetic strip.

There are an electric field components and a magnetic field component in electromagnetic waves, and the effective shielding method for each component is different. In general, when shielding a magnetic field component, it is advantageous that the magnetic material extends along a direction parallel to the magnetic field direction in a continuous manner as long as possible. When there is a region in the electromagnetic shielding material in which the magnetic material is not present in a continuous manner along a direction perpendicular to the magnetic field direction, for example, cracks, voids, and the like, the magnetic field leaks out to the outside of the magnetic material in the vicinity of the region, and electromagnetic wave shielding properties of the electromagnetic wave shielding material deteriorate. Since the flexible magnetic film fabric of the present disclosure has a woven structure of magnetic strips extending in at least two different directions, at least one group of magnetic strips is arranged to extend along a direction parallel to the magnetic field direction to some extent. Therefore, even when the direction of the magnetic field or the orientation of the flexible magnetic film fabric changes, or when the flexible magnetic film fabric deforms so that the gap between magnetic strips expands, a stable electromagnetic wave shielding effect can be obtained by suppressing a deterioration in electromagnetic wave shielding properties.

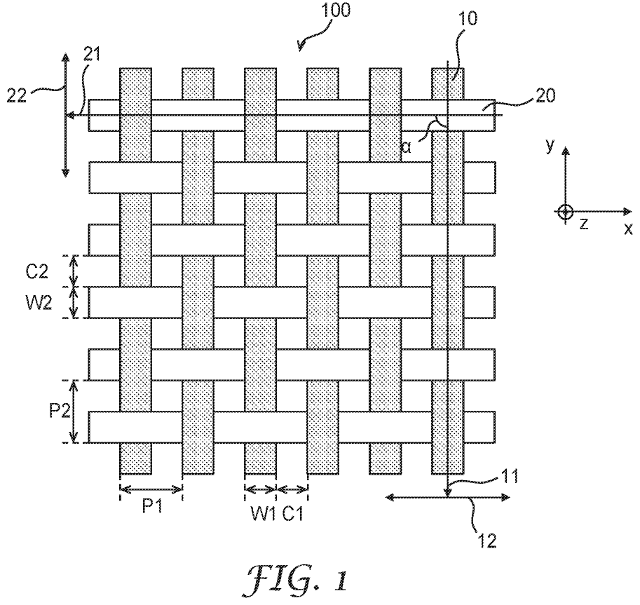

A plan view of a flexible magnetic film fabric of one embodiment is illustrated in FIG. 1.

In the flexible magnetic film fabric 100 of FIG. 1, a plurality of first magnetic strips 10 extend in a first direction 11 and are arranged substantially in parallel. In the present disclosure, “substantially in parallel” means that all of the plurality of first magnetic strips 10, or all of the plurality of second magnetic strips 20, are non-parallel to each other by ±10 degrees or less, preferably by ±5 degrees or less. Most preferably, all of the plurality of first magnetic strips 10, or all of the plurality of second magnetic strips 20, are parallel to each other. The first magnetic strips 10 are arranged at a first pitch P1 along a second direction 12 orthogonal to the first direction 11. The first magnetic strip 10 has a first average width W1. The first magnetic strip 10 is arranged away from an adjacent first magnetic strip 10 by a first gap C1. Thus, the relationship P1=W1+C1 holds.

The plurality of second magnetic strips 20 extend in a third direction 21 different from the first direction 11 and are arranged substantially in parallel. The second magnetic strips 20 are arranged at a second pitch P2 along a fourth direction 22 orthogonal to the third direction 21. The second magnetic strip 20 has a second average width W2. The second magnetic strip 20 is arranged away from an adjacent second magnetic strip 20 by the second gap C2. Thus, the relationship P2=W2+C2 holds.

In one embodiment, the W1/P1 and W2/P2 independently are each about 0.05 or greater, about 0.15 or greater, or about 0.2 or greater, about 0.98 or less, about 0.95 or less, or about 0.8 or less. By setting the W1/P1 and the W2/P2 to about 0.05 or greater, the area occupied by the first magnetic strip 10 and the second magnetic strip 20 in the plane of the flexible magnetic film fabric 100 can be made large enough to impart electromagnetic wave shielding properties and strength to the flexible magnetic film fabric 100. Setting the W1/P1 and the W2/P2 to about 0.98 or less allows that gaps are secured in which adjacent first magnetic strips 10 and adjacent second magnetic strips 20 can be shifted and moved with respect to each other. This allows the flexible magnetic film fabric 100 to be deformed when applied to a three-dimensional shape so as to follow the shape thereof.

In one embodiment, the ratio of W1/P1 to W2/P2 is between 1:4 and 4:1, between 1:2 and 2:1, or between 1:1.1 and 1.1:1. By setting the ratio of W1/P1 to W2/P2 to between 1:4 and 4:1, directivity (direction dependency) in electromagnetic wave shielding properties in the plane of the flexible magnetic film fabric 100 can be suppressed.

The average width W1 of the first magnetic strip 10 and the average width W2 of the second magnetic strip 20 may vary depending on the intended use of the flexible magnetic film fabric 100, the electromagnetic shielding properties required, shape following properties, strength, and the like. For example, each of W1 and W2, independently, can be about 1 mm or greater, about 2 mm or greater, about 3 mm or greater, about 50 mm or less, about 30 mm or less, or about 20 mm or less.

The first magnetic strip 10 and the second magnetic strip 20 are woven having a relationship of one being the warp thread and the other being the weft thread. Weaving texture of a flexible magnetic film fabric is not particularly limited, but may include a plain weave, a twill weave, a satin weave, and modifications of such weaves. A plain weave is advantageous as the weaving texture of a flexible magnetic film fabric, because it has excellent strength and low directivity (direction dependency) in electromagnetic wave shielding properties in the plane of the flexible magnetic film fabric 100.

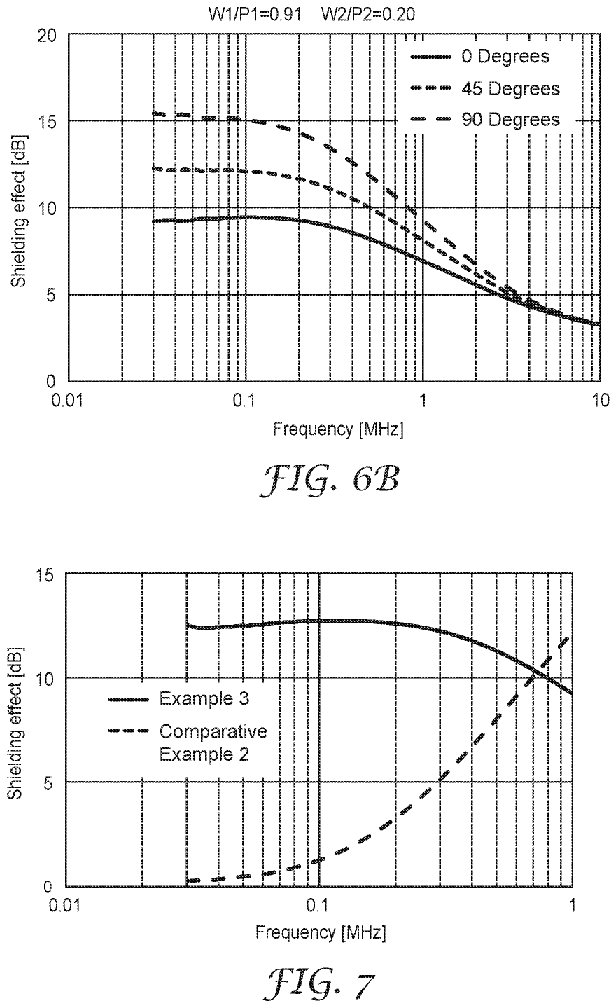

In an embodiment, when the acute angle α is formed between the first direction 11 of the first magnetic strip 10 and the third direction 21 of the second magnetic strip 20, the acute angle α is substantially 90 degrees, for example, about 85 degrees or greater, about 88 degrees or greater, or about 89 degrees or greater and, 90 degrees or less. When the acute angle α is substantially 90 degrees, the directionality (direction dependency) in electromagnetic wave shielding properties in the plane of the flexible magnetic film fabric 100 can be substantially eliminated, for example, as shown in FIG. 6A. In FIG. 1, a flexible magnetic film fabric 100 having an acute angle α of substantially 90 degrees is illustrated.

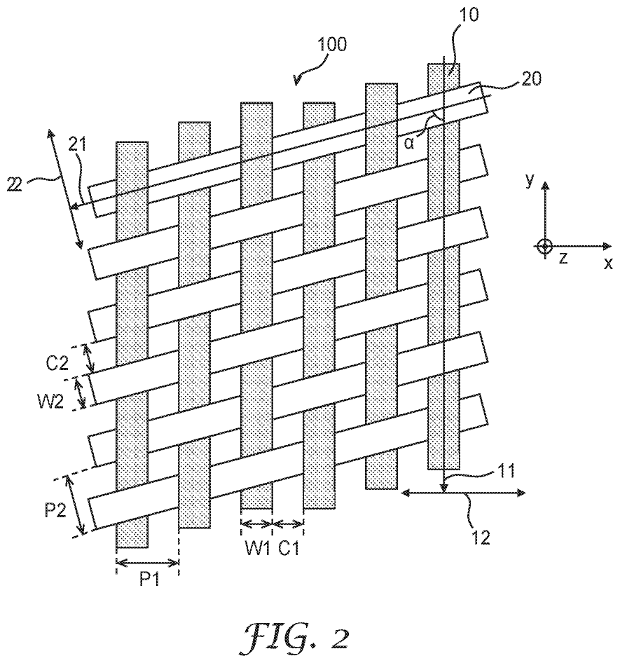

In another embodiment, the acute angle α is about 15 degrees or greater, about 25 degrees or greater, or about 45 degrees or greater, less than about 85 degrees, about 82 degrees or less, or about 80 degrees or less. When the acute angle α is greater than or equal to about 15 degrees, a woven material can be obtained that is little affected by directionality (direction dependency) in electromagnetic wave shielding properties in the plane of the flexible magnetic film fabric 100. When the acute angle α is less than about 85 degrees, degradation of electromagnetic wave shielding properties can be suppressed when the flexible magnetic film fabric 100 is processed or deformed into a shape with a high curvature, for example, a cylindrical shape. In FIG. 2, a flexible magnetic film fabric 100 having an acute angle α of substantially less than 90 degrees is illustrated in a plan view.

The flexible magnetic film fabric may, in addition to the first magnetic strip 10 and the second magnetic strip 20, further include a third magnetic strip that extends in a different direction than any of the first direction 11 and the third direction 21. Such a flexible magnetic film fabric can be formed as a triaxial weave. For example, a first magnetic strip 10, a second magnetic strip 20, and a third magnetic strip may intersect at an angle of substantially 60 degrees with each other. Alternatively, the first magnetic strip 10 and the second magnetic strip 20 may be substantially orthogonal, and the third magnetic strip may intersect with either of the first magnetic strip 10 and the second magnetic strip 20 at substantially 45 degrees.

The flexible magnetic film fabric of the present disclosure can be applied to objects of various three-dimensional shapes by changing the W1/P1, the W2/P2, and the acute angle α to impart electromagnetic shielding properties to these three-dimensional shapes. The flexible magnetic film fabric of the present disclosure can be applied not only to a cube or cuboid housing or container, but also to a cylinder, sphere, or the like, such as a cable sleeve.

In an embodiment, the first magnetic strip 10 and the second magnetic strip 20 include at least one selected from the group consisting of a soft magnetic ferrite, a crystalline soft magnetic metal, a crystalline soft magnetic alloy, a nanocrystalline soft magnetic alloy, and an amorphous soft magnetic alloy as a magnetic material.

As a soft magnetic ferrite, one containing at least one selected from the group consisting of manganese-zinc ferrite and nickel-zinc ferrite can be used. In one embodiment, the coercive force of the soft magnetic ferrite is no greater than about 1000 A/m, no greater than about 100 A/m, no greater than about 50 A/m, or no greater than about 20 A/m.

Examples of crystalline soft magnetic metals include pure iron.

As the crystalline soft magnetic alloy, an alloy comprising at least two selected from the group consisting of iron, cobalt, nickel, silicon, aluminum, boron, niobium, copper, cobalt, nickel, chromium, and molybdenum can be used. Such crystalline soft magnetic alloys include, for example, sendust and permalloy.

A nanocrystalline soft magnetic alloy is a material in which nanocrystalline grains that are ferromagnetic phases are dispersed in an amorphous phase. As the nanocrystalline soft magnetic alloy, an alloy may be used that includes iron as a main component and further includes at least one selected from the group consisting of silicon, boron, niobium, and copper. The nanocrystalline soft magnetic alloy has excellent absorption properties of electromagnetic waves in the kilohertz band. On the other hand, metals commonly known as electromagnetic shielding materials do not absorb or absorb little, if any, electromagnetic waves in the kilohertz band. By using a magnetic strip that includes a nanocrystalline soft magnetic alloy, electromagnetic shielding properties in the kilohertz band can be imparted to a flexible magnetic film fabric, the properties not obtainable with electromagnetic shielding materials woven from conventional metal threads.

The nanocrystalline soft magnetic alloy can be obtained by forming a thin layer by an ultra-quench method such as a single roll method in which an alloy melt containing an alloy component is blown to and wound on a rotating roll, and heat treating the obtained thin layer at a crystallization temperature to promote crystallization.

Examples of such a nanocrystalline soft magnetic alloy include, for example, an alloy containing iron as a principal constituent and silicon, boron, niobium, and copper as the alloy component, and 50% or more of the total volume of the alloy texture is constituted by fine nanocrystalline grains with a mean particle size of 100 nm or less, such as Finemet® (Hitachi Metals, Ltd., Minato-ku, Tokyo, Japan).

An alloy comprising cobalt or iron and at least one selected from the group consisting of silicon and boron can be used as the amorphous soft magnetic alloy. Examples of such amorphous soft magnetic alloys include Metglas® (Hitachi Metals, Ltd., Minato-ku, Tokyo, Japan).

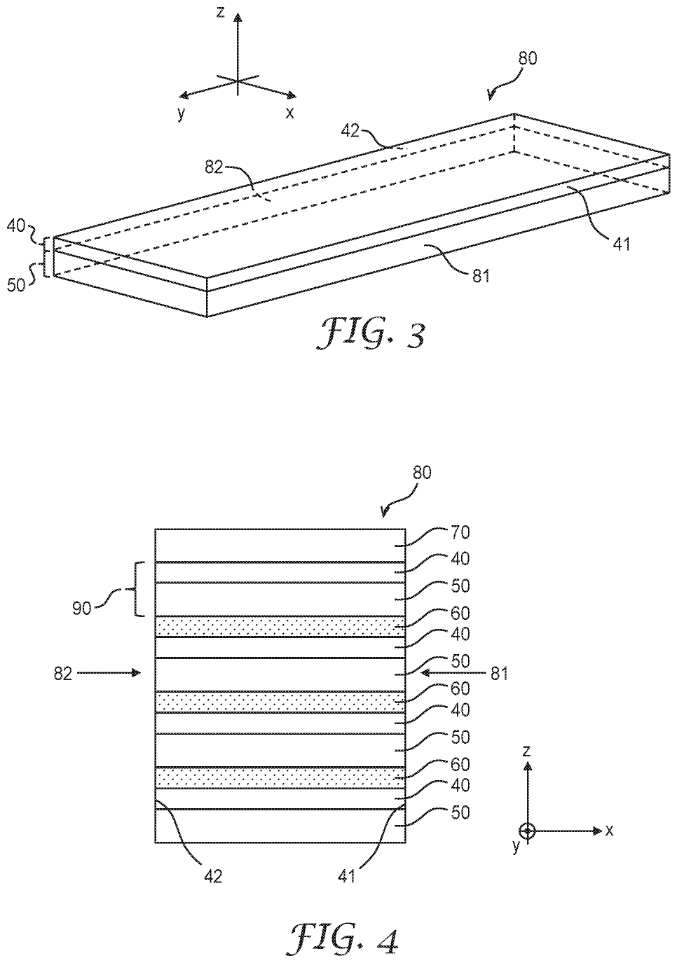

In an embodiment, as illustrated in perspective view in FIG. 3, the first magnetic strip 10 and the second magnetic strip 20 are each a multilayer strip 80 that includes a magnetic layer 40. The magnetic layer 40 is a layer containing the magnetic material, or a layer formed from the magnetic material. The thickness of the magnetic layer 40 can be, for example, about 5 μm or greater, about 10 μm or greater, about 15 μm or greater, or about 40 μm or less, about 35 μm or less, or about 30 μm or less.

The longitudinal ends 41, 42 on opposite sides of the magnetic layer 40 are advantageously exposed at corresponding opposing longitudinal ends 81, 82 of the multilayer strip 80. By the longitudinal ends 41, 42 being exposed in this manner on opposite sides of the magnetic layer 40 in this manner, the distance between adjacent magnetic layers can be made smaller, that is, adjacent magnetic layers can be made closer to each other, and electromagnetic wave shielding performance can be improved. Such a multilayer strip 80 can be manufactured by cutting a multilayer sheet or multilayer roll including the magnetic layer 40 into elongated strips, the cut ends thereof constituting longitudinal ends 41, 42.

The cross-sectional shape of the magnetic layer 40 may vary, such as square, elliptical, and the like, and the height and width aspect ratios can be about 10 or higher, about 15 or higher, or about 25 or higher, and about 5000 or lower, about 4000 or lower, or about 3000 or lower.

In an embodiment, as illustrated in FIG. 3, the first magnetic strip 10 and the second magnetic strip 20 are each a multilayer strip 80 that includes a magnetic layer 40 and a support layer 50. The support layer 50 can be, for example, a film or sheet including polyester, such as polyethylene terephthalate (PET), polycarbonate, polyvinyl chloride, polyamide, polyimide, or the like. The multilayer strip 80 can be formed, for example, by adhering a film or sheet onto the magnetic layer 40 using an adhesive such as an acrylic-based adhesive, a rubber-based adhesive, a silicone-based adhesive, or the like, or extruding the film directly onto the magnetic layer 40. The adhesive may be a pressure sensitive adhesive. The pressure sensitive adhesive may not only adhere the magnetic layer 40 and the support layer 50 together, but may also increase the flexibility of the multilayer strip 80. The multilayer strip 80 may be formed by coating the support layer 50, which is a solution comprising a resin such as a polyether resin a polyester resin, an epoxy resin, an alkyd resin, a spiroacetal resin, a polybutadiene resin, a polythiolpolyene resin, having polyfunctional (meth) acrylate compound such as acrylic acid or methacrylic acid ester of a polyhydric alcohol, a polyfunctional urethane (meth) acrylate compound synthesized from a diisocyanate, a polyhydric alcohol, and a hydroxy ester of acrylic acid or methacrylic acid, an acrylate functional group, onto the magnetic layer 40. The thickness of the support layer 50 can be, for example, about 1 μm or greater, about 3 μm or greater, or about 5 μm or greater, and can be about 200 μm or less, about 180 μm or less, or about 150 μm or less.

Nanocrystalline soft magnetic alloys are relatively stiff, for example in thin layers alone, and may break upon deformation. By configuring the first magnetic strip 10 or the second magnetic strip 20 to be a multilayer strip 80 that includes a magnetic layer 40 and a support layer 50, the flexibility of the magnetic strip including the nanocrystalline soft magnetic alloy can be increased.

The multilayer strip 80 may be a layer in which a magnetic layer 40 interposed between two support layers 50. In such embodiment, the surface of the magnetic layer 40 can be protected so that damage to the magnetic layer 40 can be more effectively prevented or reduced.

The magnetic layer 40 and the support layer 50 are advantageously substantially identical in size with respect to at least the width. Due to the width of the magnetic layer 40 and the support layer 50 being substantially the same size, compared to the case in which the support layer 50 is wider than the magnetic layer 40, the distance between adjacent magnetic layers can be made smaller, that is, adjacent magnetic layers are closer to each other, thereby enabling electromagnetic wave shielding performance to be improved. On the other hand, when the magnetic layer 40 is wider than the support layer 50, an end portion is created in which the magnetic layer 40 is a single layer not supported by the support layer 50, and the magnetic layer 40 can be damaged at this end portion. Such damage to the end portion of the magnetic layer 40 can be prevented by making the width of the magnetic layer 40 and the support layer 50 substantially the same. The length of the magnetic layer 40 and the support layer 50 may be substantially the same size. Such a multilayer strip 80 can be made by cutting a multilayer sheet or multilayer roll including a magnetic layer 40 and a support layer 50 perpendicularly in the thickness direction.

The support layer 50 may optionally include additives such as inorganic fillers, reinforcing fibers, flame retardants, conductivity imparting agent, ultraviolet absorbers, antioxidants, thermal stabilizers, antistatic agents, plasticizers, lubricants, colorants, pigments, dyes, and the like.

The multilayer strip 80 may include a plurality of magnetic layers 40 and a plurality of support layers 50. For example, as illustrated in the schematic cross-sectional view in FIG. 4, each of the magnetic layers 40 may be arranged on a corresponding support layer 50 to form a plurality of repeat units 90 stacked along the thickness direction of the multilayer strip 80. The number of repeat units 90 can be, 2, 3, 4 or 5, for example. Such a multilayer strip 80 may be used as a first magnetic strip 10 or a second magnetic strip 20 that includes at least two spaced-apart magnetic layers 40 stacked along the thickness direction. By using a multilayer strip 80 including the plurality of magnetic layers 40 as the first magnetic strip 10 or the second magnetic strip 20, deterioration in electromagnetic wave shielding properties can be suppressed in the event a damage such as breakage occurs in one magnetic layer 40 during deformation of the magnetic strip, as long as a damage is not simultaneously caused to the other magnetic layer 40 at a position proximate to the damaged part.

The adjacent repeat units 90 of the multilayer strip 80 may be bonded by an adhesive layer 60, as illustrated in FIG. 4. The adhesive layer 60 may include a pressure sensitive adhesive. The adhesive layer 60 that includes a pressure sensitive adhesive may not only adhere the layers constituting the multilayer strip 80, but also be capable of increasing the flexibility of the multilayer strip 80. Examples of the adhesive layer 60 include acrylic-based adhesives, rubber-based adhesives, silicone-based adhesives, and the like. The thickness of the adhesive layer 60 can be set to about 1 μm or greater, about 5 μm or greater, or about 10 μm or greater, and about 200 μm or less, about 150 μm or less, or about 100 μm or less.

As illustrated in FIG. 4, the multilayer strip 80 may include a surfacing layer 70 as an outermost layer. The surfacing layer 70 may be disposed over the magnetic layer 40. The surfacing layer 70 may be the same material as the support layer 50, and may be, for example, a coating with an acrylic resin, polyurethane, or the like. The thickness of the surfacing layer 70 may be, for example, about 1 μm or greater, about 5 μm or greater, or about 10 μm or greater, and about 200 μm or less, about 150 μm or less, or about 100 μm or less. In this embodiment, other layers constituting the multilayer strip 80, such as the magnetic layer 40, may be protected to prevent or reduce damage to these layers.

In one embodiment, the average thickness of each of the first magnetic strip and the second magnetic strip independently is about 20 μm or greater, about 30 μm or greater, or about 50 μm or greater, and about 2 mm or less, about 1.5 mm or less, or about 1 mm or less. By setting the average thickness of the first magnetic strip 10 and the second magnetic strip 20 to be about 20 μm or greater, it is possible to increase the strength and electromagnetic wave shielding properties of the flexible magnetic film fabric 100. By setting the average thickness of the first magnetic strip 10 and the second magnetic strip 20 to be about 2 mm or less, it is possible to increase the shape following properties of the flexible magnetic film fabric 100.

The length of the first magnetic strip 10 and the second magnetic strip 20 may vary depending on the intended use of the flexible magnetic film fabric 100, the required dimensions, and the like. For example, each of the length of the first magnetic strip 10 and the length of the second magnetic strip 20 independently can be set to about 5 cm or greater, about 10 cm or greater, or about 20 cm or greater and about 5 m or less, about 3 m or less, or about 1 m or less.

In one embodiment, the tensile stress when the first magnetic strip 10 and the second magnetic strip 20 are stretched 0.5% is about 0.5 MPa or greater, about 1 MPa or greater, or about 10 MPa or greater. As the magnetic layer 40 normally has poor elasticity as described above, the magnetic layer 40 can be made to follow various surfaces such as curved surfaces by adopting the woven structure according to the present disclosure. The tensile stress when the first magnetic strip 10 and the second magnetic strip 20 are stretched 0.5% is determined from the measured load and the sample cross-sectional area at the start of the measurement by, producing from a 25 μm thick magnetic strip a sample having a measurement part of 100 mm length and 50 mm width, using a Tensilon universal material testing machine RTC-1325A (available from A&D Company, Limited, Toshima-ku, Tokyo), and performing measurements using a 1 kN load cell at a temperature of 25° C. and a tensile speed of 10 mm/min.

In one embodiment, when the flexible magnetic film fabric 100 is laid flat, the aperture ratio of the flexible magnetic film fabric 100 was about 10% or greater, about 20% or greater, or about 30% or greater, and about 90% or less, about 80% or less, or about 70% or less. By making the aperture ratio of the flexible magnetic film fabric 100 to be about 10% or greater, flexibility can be obtained. By setting the aperture ratio of the flexible magnetic film fabric 100 to be about 90% or less, electromagnetic wave shielding properties can be ensured.

The flexible magnetic film fabric 100 of the second embodiment includes a plurality of magnetic strips 10, 20 extending in at least two different directions 11, 21. Each of the plurality of magnetic strips 10, 20 includes at least two spaced-apart magnetic layers 40 stacked along a thickness direction of the magnetic strips 10, 20. The flexible magnetic film fabric 100 is configured, when it is made to follow vertices or edges of a cube, to be reversibly deformable to the shape of the cube, without damage or with no substantial damage to the magnetic strip 10, 20. The material, structure, configuration, and arrangement of the plurality of magnetic strips 10, 20 in the flexible magnetic film fabric 100 may be the same as that described for the first embodiment.

In one embodiment, when a value of a magnetic shielding property of the flexible magnetic film fabric 100 laid flat before being deformed to the shape of the cube is set to V1, and the value when laid flat after being deformed into the shape of the cube is set to V2, V2/V1 is equal to or greater than about 80%, equal to or greater than about 85%, or equal to or greater than about 90%. V2/V1 represents the resistance to deformation of the flexible magnetic film fabric 100 in terms of the rate of change of the magnetic shielding properties, and a higher value means a greater resistance to deformation. Magnetic shielding properties are measured by KEC method in the frequency range of 30 kHz to 1 MHz. The KEC method refers to a measurement of electromagnetic wave shielding properties using an electromagnetic wave shielding effect measuring device developed by KEC Electronic Industry Development Center.

The flexible magnetic film fabric of the present disclosure can be used in a variety of applications, such as automotive parts. Automotive applications include, for example, main motors and motor inverters, charging DC/DC converters, air conditioners, HID lamp inverters and harnesses, radiator motors and inverters, water pump motors and controllers, LED head lamps and controllers, EV mode speaker amplifiers, fuel pump motors; power window motors and inverters, WPC (Wireless Power Consortium) TX (power transmission) and RX (reception), intra-vehicle battery charger, current harnesses for main motors, HID lamp units and harnesses, resolvers, air flow sensors, CVT position sensors, clearance sensors, AM radio and antennas.

### EXAMPLES

Specific embodiments of the present disclosure will be exemplified in the following examples, but the present invention is not limited to these embodiments. All parts and percentages are based on mass unless otherwise specified.

The materials used to make the flexible magnetic film fabric of the present example are shown in Table 1.

TABLE 1

| Item name or | | |
|---|---|---|
| abbreviation | Description | Supplier |
| 3M ™ Flux Field | Noise suppression sheet | 3M Japan Limited |
| Directional Material | using nanocrystalline soft | (Shinagawa-ku, |
| EM80KM-011-1 | magnetic material | Tokyo, Japan) |

### Manufacturing of Magnetic Film

The liner was peeled off the above-mentioned noise suppression sheet with a thickness of about 50 μm (constituted by a black polyethylene terephthalate (PET) film, a thin layer of nanocrystalline soft magnetic material with a thickness of 20 μm, an adhesive layer, and a liner.), and a transparent PET film with a thickness of 12 μm was laminated. The nanocrystalline soft magnetic material is a nanocrystalline soft magnetic alloy containing iron as a principal constituent and including silicon and boron as well as trace amounts of copper and niobium as alloying components, with 50% or more of the total volume of the alloy texture composed of fine nanocrystalline grains with a mean particle size of 100 nm or less.

### Example 1 to Example 14

The obtained magnetic film was cut into strips of 3 mm, 4 mm, 7 mm, or 10 mm width using a cutter knife to produce magnetic strips. Samples of the flexible magnetic film fabric of Examples 1 to 14 were prepared by weaving in plain weave the obtained magnetic strips as first magnetic strips and second magnetic strips. The dimensions and positional relationships of the first magnetic strips and the second magnetic strips were adjusted as shown in Table 2. W1, C1 and P1 respectively mean the average width of the first magnetic strip as well as the pitch and the gap between adjacent first magnetic strips, and W2, C2 and P2 respectively mean the average width of the second magnetic strip as well as the pitch and the gap between adjacent second magnetic strips.

### Shielding Effect

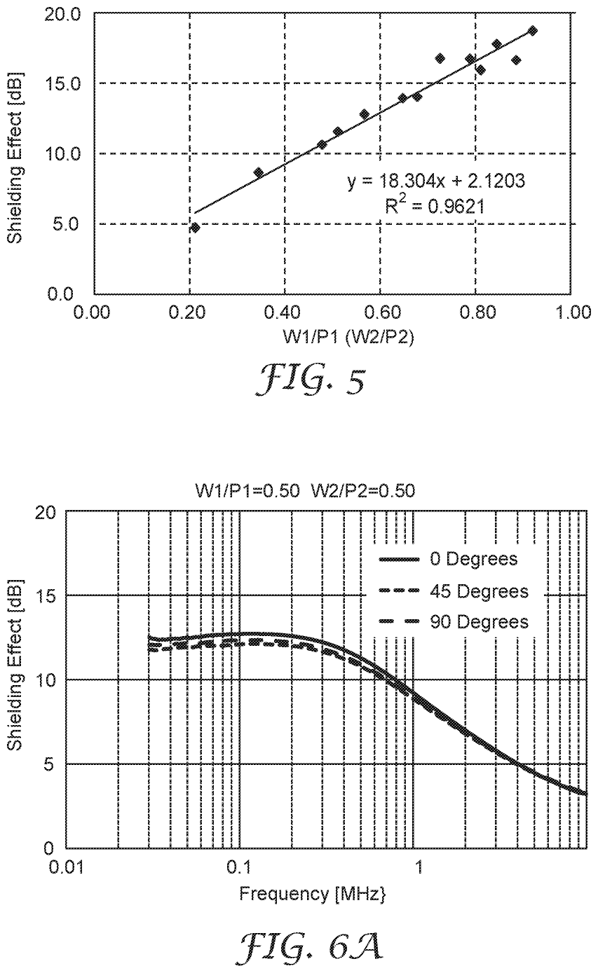

As a method for evaluating the shielding properties of electromagnetic waves incident on an electromagnetic wave shielding material, the KEC method developed by KEC Electronic Industry Development Center is known. In this KEC method, a sample is inserted between an antenna for transmitting signals and an antenna for receiving signals disposed in a space shielded by a metal tube, and the shielding effect is determined from the difference in strength of the electric field with or without the sample. In the present example, using a magnetic field wave at a frequency of 30 kHz, a 1 mm thick copper plate with a 30 mm diameter hole was placed so that the center of the hole was located on a line connecting the centers of the two loops of a pair of loop antennas (for signal transmission and reception), and a 50 mm square measurement sample was attached to the copper plate so as to completely cover the hole in the copper plate, and the shielding effect was measured. The shielding effect was determined from the measurement as the average of the measured value, with the angles, formed by the direction in which the first magnetic strip of the sample extends with respect to the magnetic field, of 0 degrees, 45 degrees, or 90 degrees, using the equation below. The results are shown in Table 2 along with the measurement of the shielding effect at 0 degrees, 45 degrees, and 90 degrees. Also, for Examples 1 to 13, in which the W1/P1 and the W2/P2 are the same, the relationship of the shielding effect to the value of W1/P1 (W2/P2) is graphically illustrated in FIG. 5.
Field intensity of space without sample H0 [A/m]
Field intensity of space with sample Hx [A/m]
Shielding effect=|20 log 10H0/Hx| [dB]

TABLE 2

| | | | | | | | | | α | | | | |
|---|---|---|---|---|---|---|---|---|---|---|---|---|---|
| | First magnetic strip | | | | Second magnetic strip | | | | (degrees) | Shielding effect @30 kHz (dB) | | | |
| | W1 | C1 | P1 | W1/P1 | W2 | C2 | P2 | W2/P2 | 90 | 0 degrees | 45 degrees | 90 degrees | Average |
| Example 1 | 4 | 1 | 5 | 0.80 | 4 | 1 | 5 | 0.80 | 90 | 15.4 | 15.9 | 16.5 | 15.9 |
| Example 2 | 4 | 2 | 6 | 0.67 | 4 | 2 | 6 | 0.67 | 90 | 13.4 | 14.0 | 14.7 | 14.0 |
| Example 3 | 4 | 4 | 8 | 0.50 | 4 | 4 | 8 | 0.50 | 90 | 12.0 | 11.3 | 11.4 | 11.5 |
| Example 4 | 4 | 8 | 12 | 0.33 | 4 | 8 | 12 | 0.33 | 90 | 7.5 | 8.5 | 10.0 | 8.7 |
| Example 5 | 7 | 1 | 8 | 0.88 | 7 | 1 | 8 | 0.88 | 90 | 16.2 | 16.9 | 16.9 | 16.6 |
| Example 6 | 7 | 2 | 9 | 0.78 | 7 | 2 | 9 | 0.78 | 90 | 15.7 | 16.6 | 17.9 | 16.7 |
| Example 7 | 7 | 4 | 11 | 0.64 | 7 | 4 | 11 | 0.64 | 90 | 13.2 | 13.8 | 14.8 | 13.9 |
| Example 8 | 7 | 8 | 15 | 0.47 | 7 | 8 | 15 | 0.47 | 90 | 10.1 | 10.6 | 11.2 | 10.6 |
| Example 9 | 10 | 1 | 11 | 0.91 | 10 | 1 | 11 | 0.91 | 90 | 18.1 | 18.9 | 19.2 | 18.7 |
| Example 10 | 10 | 2 | 12 | 0.83 | 10 | 2 | 12 | 0.83 | 90 | 17.5 | 18.2 | 17.7 | 17.8 |
| Example 11 | 10 | 4 | 14 | 0.71 | 10 | 4 | 14 | 0.71 | 90 | 16.4 | 17.0 | 16.8 | 16.8 |
| Example 12 | 10 | 8 | 18 | 0.56 | 10 | 8 | 18 | 0.56 | 90 | 12.0 | 12.6 | 13.8 | 12.8 |
| Example 13 | 3 | 12 | 15 | 0.20 | 3 | 12 | 15 | 0.20 | 90 | 4.7 | 4.5 | 5.0 | 4.7 |
| Example 14 | 10 | 1 | 11 | 0.91 | 3 | 12 | 15 | 0.20 | 90 | 9.2 | 12.3 | 15.4 | 12.3 |

### Frequency Dependence

For the samples of Examples 3 and 14, the frequency dependence of the shielding effect measured by changing the frequency of the magnetic field wave from 30 KHz to 10 MHz is shown in FIG. 6A and FIG. 6B respectively, at angles, formed by the direction in which the first magnetic strip of the sample extends with respect to the magnetic field, of 0 degrees, 45 degrees and 90 degrees.

### Example 15

The magnetic film was cut into strips of 3 mm width and 50 mm length using a cutter knife to produce magnetic strips. A sample of the flexible magnetic film fabric of Example 15 was prepared by weaving in plain weave the obtained magnetic strips as first magnetic strips and second magnetic strips. W1/P1 and W2/P2 were set to 0.5 respectively.

### Comparative Example 1

The magnetic film was used as a sample as is.

### Retention Ratio of Shielding Effect

The shielding effect of the samples of Example 15 and Comparative Example 1 were measured. Thereafter, the sample was placed on the cushion foam (3M® E-A-R CF-40EG, 40 mm thickness×100 mm width×100 mm length) and a ball having diameters of 43 mm, 30 mm, or 16 mm was then pressed down to a depth of 20 mm and retained for 30 seconds before being returned to a flat state, and then the shielding effect was measured. The retention ratio of the shielding effect after being pressed down (=shielding effect after being pressed down/shielding effect before being pressed down×100%) was evaluated for shape following properties. The shielding effect was measured in the same manner as in Example 1 to 14 with the exception that the frequency of the magnetic field wave was set to 30 kHz, 60 kHz, 90 kHz or 120 kHz, and was determined from the measurement as the average of the measured value, with the angles, formed by the direction in which the first magnetic strip of the sample extends with respect to the magnetic field, of 0 degrees, 45 degrees, or 90 degrees. The results are shown in Table 3.

TABLE 3

| | | Ball diameter (mm) | | | | | |
|---|---|---|---|---|---|---|---|
| | | 43 | | 30 | | 16 | |
| | | Comparative | Example | Comparative | Example | Comparative | Example |
| | | example 1 | 15 | example 1 | 15 | example 1 | 15 |
| Retention | 30 kHz | 75 | 98 | 71 | 100 | 63 | 100 |
| ratio of | 60 kHz | 76 | 98 | 68 | 100 | 64 | 100 |
| shielding | 90 kHz | 76 | 98 | 67 | 100 | 65 | 100 |
| effect (%) | 120 kHz | 76 | 98 | 66 | 100 | 65 | 100 |

### Comparative Example 2

A braided shield material (3M® electromagnetic guard sleeve FS-30, 3M Japan Limited (Shinagawa-ku, Tokyo, Japan)) made by weaving a conductive yarn obtained by winding a tin plated copper foil around glass fibers was cut to 5 cm×5 cm, and the resulting conductive woven fabric was used as a sample.

### Frequency Dependence

For the samples of Example 3 and Comparative Example 2, the frequency dependence of the shielding effect as measured by changing the frequency of the magnetic field wave from 30 KHz to 1 MHz is shown in FIG. 7. The shielding effect of the sample of Example 3 was measured at the angle of 0 degrees formed by the direction in which the first magnetic strip of the sample extends with respect to the magnetic field.

### Tensile Stress

The tensile stress measurement of the magnetic strip was performed under the following conditions. A sample having a length of 100 mm and a width of 50 mm was produced from a magnetic strip having a total thickness of about 25 μm. Measurements were performed using a Tensilon universal material testing machine RTC-1325A (manufactured by A&D Company, Limited, Toshima-ku, Tokyo), using a 1 kN load cell at a temperature of 25° C. and a tensile speed of 10 mm/min. The tensile stress was calculated from the measured load and the sample cross-sectional area at the start of the measurement, and the extension percentage was calculated from the sample length at the start of the measurement and the tensile distance.

The tensile stress of the magnetic strip used in the present example was about 130 MPa when stretched by 0.5%.

It is clear to those skilled in the art that various modifications and changes can be made without deviating from the scope and spirit of the present invention.

### REFERENCE SIGNS LIST

100 Flexible magnetic film fabric
10 First magnetic strip
11 First direction
12 Second direction
20 Second magnetic strip
21 Third direction
22 Fourth direction
40 Magnetic layer
41, 42 Longitudinal end of magnetic layer
50 Support layer
60 Adhesive layer
70 Surfacing layer
80 Multilayer strip
81, 82 Longitudinal end of multilayer strip
90 Repeat unit
W1 First average width
P1 First pitch
C1 First gap
W2 Second average width
P2 Second pitch
C2 Second gap

1. A flexible magnetic film fabric (100) comprising:
a plurality of first magnetic strips (10) extending in a first direction (11) and arranged substantially in parallel at a first pitch P1 along a second direction (12) orthogonal to the first direction (11); and
a plurality of second magnetic strips (20) extending in a third direction (21) different from the first direction (11) and arranged substantially in parallel at a second pitch P2 along a fourth direction (22) orthogonal to the third direction (21);
wherein each of the first magnetic strips (10) has a first average width W1, W1/P1 being from 0.05 to 0.98, wherein each of the second magnetic strips (20) has a second average width W2, W2/P2 being from 0.05 to 0.98.

2. The flexible magnetic film fabric (100) according to claim 1, wherein each of the first magnetic strip (10) and the second magnetic strip (20) is a multilayer strip (80) that includes a magnetic layer (40) and has longitudinal ends (41, 42) on opposite sides of the magnetic layer (40), the longitudinal ends (41, 42) exposing at corresponding opposing longitudinal ends (81, 82) of the multilayer strip (80).

3. The flexible magnetic film fabric (100) according to claim 1, wherein each of the first magnetic strip (10) and the second magnetic strip (20) is a multilayer strip (80) that includes a magnetic layer (40) and a support layer (50), wherein the magnetic layer (40) and the support layer (50) have substantially the same size at least with respect to width.

4. The flexible magnetic film fabric (100) according to any one of claims 1, wherein the first magnetic strip (10) and the second magnetic strip (20) comprise at least one selected from the group consisting of a soft magnetic ferrite, a crystalline soft magnetic metal, a crystalline soft magnetic alloy, a nanocrystalline soft magnetic alloy, and an amorphous soft magnetic alloy.

5. The flexible magnetic film fabric (100) according to claim 4, wherein the crystalline soft magnetic alloy includes at least two selected from the group consisting of iron, cobalt, nickel, silicon, aluminum, boron, niobium, copper, cobalt, nickel, chromium and molybdenum.

6. The flexible magnetic film fabric (100) according to any one of claims 1, wherein each of W1/P1 and W2/P2 is from 0.15 to 0.95.

7. The flexible magnetic film fabric (100) according to any one of claims 1, wherein an acute angle α formed by the first direction (11) and the third direction (21) is greater than or equal to 15 degrees.

8. The flexible magnetic film fabric (100) according to any one of claims 1, wherein the ratio of W1/P1 to W2/P2 is 1:4 to 4:1.

9. A flexible magnetic film fabric (100) comprising a plurality of magnetic strips (10, 20) extending in at least two different directions (11, 21), each of the plurality of magnetic strips (10, 20) comprising at least two spaced-apart magnetic layers (40) stacked in a thickness direction of the magnetic strip (10, 20), wherein the flexible magnetic film fabric (100) is configured, when it is made to follow vertices or edges of a cube, to be reversibly deformable to the shape of the cube, without damage or with no substantial damage to the magnetic strip (10, 20).

10. The flexible magnetic film fabric (100) according to claim 9, wherein V2/V1 is equal to or greater than 80% when a value of a magnetic shielding property of the flexible magnetic film fabric (100) laid flat before being deformed to the shape of the cube is set to V1, and the value when laid flat after being deformed into the shape of the cube is set to V2.

11. The flexible magnetic film fabric (100) according to claim 4, wherein the nanocrystalline soft magnetic alloy includes iron as a principal constituent and further includes at least one selected from the group consisting of silicon, boron, niobium, and copper.

12. The flexible magnetic film fabric (100) according to claim 4, wherein the amorphous soft magnetic alloy includes cobalt or iron and at least one selected from the group consisting of silicon and boron.

13. The flexible magnetic film fabric (100) according to claim 1, wherein an acute angle a formed by the first direction (11) and the third direction (21) is substantially 90 degrees.
